(19) United States
(12) Patent Application Publication
(10) Pub. No.: US 2014/0016267 A1
(43) Pub. Date: Jan. 16, 2014

(54) ELECTRONIC DEVICE WITH HEAT INSULATION LAYER

(71) Applicants: HENG-SHENG LIN, Tu-Cheng (TW); RUNG-AN CHEN, Tu-Cheng (TW)

(72) Inventors: HENG-SHENG LIN, Tu-Cheng (TW); RUNG-AN CHEN, Tu-Cheng (TW)

(21) Appl. No.: 13/660,029

(22) Filed: Oct. 25, 2012

(30) Foreign Application Priority Data
Jul. 11, 2012 (TW) 101124891

(51) Int. Cl. H05K 7/20

(52) U.S. Cl. 361/692; 361/704; 361/696

(57) ABSTRACT

An exemplary electronic device includes an electronic component, a heat dissipation device, a casing, and a heat insulation layer. The heat dissipation device is positioned on the electronic component for dissipating heat generated by the electronic component. The electronic component and the heat dissipation device are located at an inner side of the casing. The heat insulation layer is located on the heat dissipation device and is close to the casing. The heat insulation layer is made of aerogel material.

### BACKGROUND

1. Technical Field

The disclosure relates to electronic devices, and particularly to an electronic device with a heat dissipation device and a casing.

2. Description of Related Art

With the continuing development of electronic devices, the electronic components in many kinds of modern electronic devices generate a large amount of heat during operation. Thus a heat dissipation device is needed for dissipating the heat of such electronic device.

However, the interior space of many electronic devices is very limited. In such case, the heat dissipating device is often positioned close to the casing of the electronic device. The heat generated by the electronic components is absorbed by the heat dissipation device, and then is liable to pass to the casing. Thus may cause the casing to have a relatively high temperature, which in turn may discomfort or inconvenience the user of the electronic device.

What is needed, therefore, is an electronic device which can overcome the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an isometric, assembled view of part of an electronic device in accordance with a first embodiment of the disclosure.

FIG. 2 is an exploded view of the electronic device of FIG. 1 when the electronic device is inverted.

FIG. 3 is an enlarged, side cross-sectional view of part of a preform of the electronic device of FIG. 1, corresponding to line III-III thereof, and showing a bottom surface of a fin assembly of the electronic device positioned in contact with aerogel solution.

FIG. 4 is an exploded view of part of an electronic device in accordance with a second embodiment of the disclosure.

### DETAILED DESCRIPTION

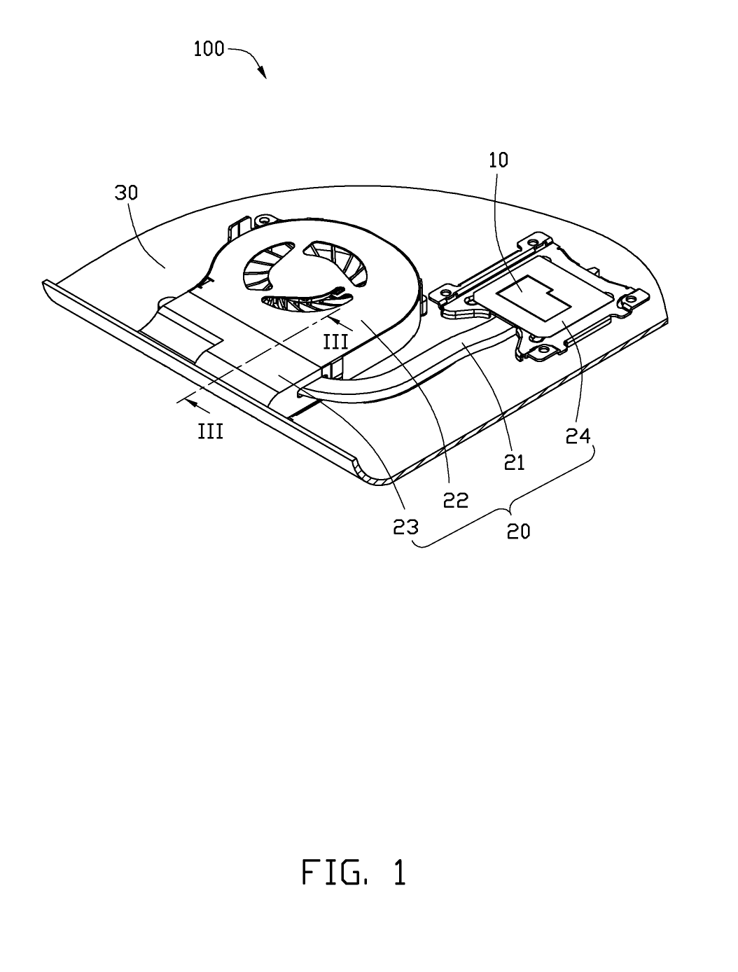

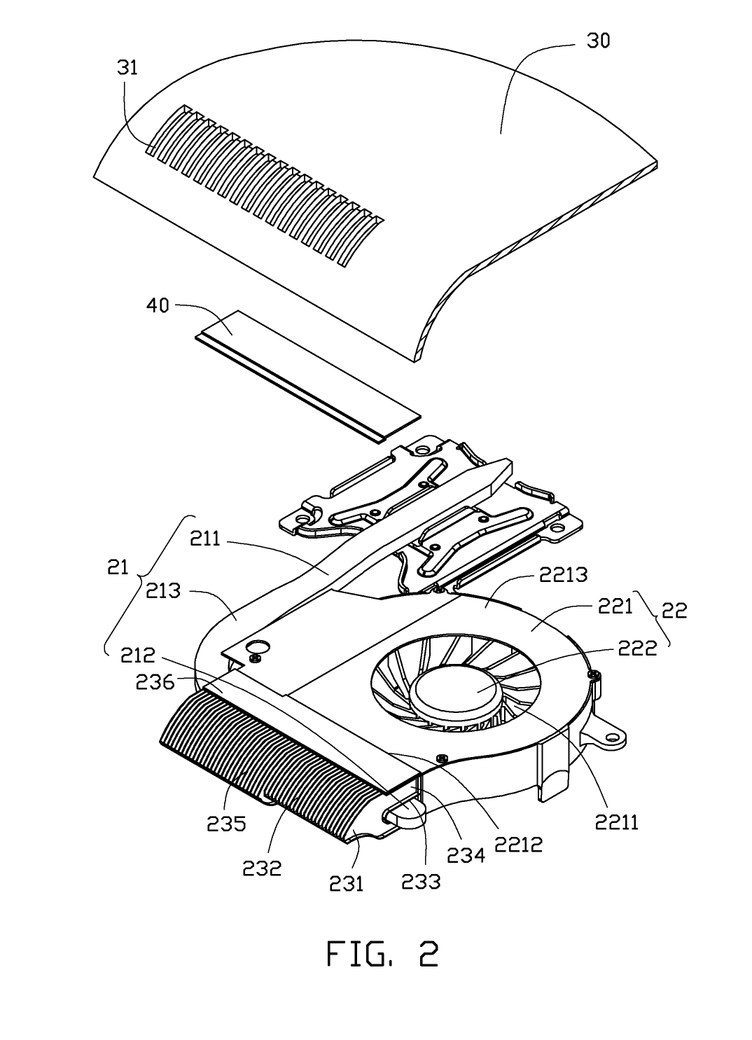

Referring to FIGS. 1 and 2, an electronic device 100 in accordance with a first embodiment of the present disclosure is shown. The electronic device 100 includes an electronic component 10, a heat dissipation device 20, a casing 30, and a heat insulation layer 40. The electronic component 10 and the heat dissipation device 20 are located at the same side of the casing 30, that is, at an inner side of the casing 30.

The heat dissipation device 20 is used for dissipating heat generated by the electronic component 10, and includes a centrifugal fan 22, a heat pipe 21 surrounding the centrifugal fan 22, a fin assembly 23 thermally connected to one end of the heat pipe 21, and a heat absorbing plate 24 thermally contacting the electronic component 10.

The heat pipe 21 can be flat, and has an L-shaped configuration. The heat pipe 21 includes an evaporating section 211, a condensing section 212, and a connecting section 213 interconnecting the evaporating section 211 and the condensing section 212.

The centrifugal fan 22 includes a hollow frame 221, and an impeller 222 mounted in the frame 221. The frame 221 is approximately cuboid shaped. A fan air inlet 2211 is defined in a center of a bottom wall of the frame 221. A fan air outlet 2212 is defined in a lateral side of the fan frame 221. An orientation of an opening of the fan air outlet 2212 is substantially perpendicular to an orientation of an opening of the fan air inlet 2211, and the fan air outlet 2212 is communicated with the fan air inlet 2211 via an interior of the frame 221. The frame 221 includes a bottom cover 2213 surrounding the fan air inlet 2211.

The fin assembly 23 is made of metal, and located adjacent to the fan air outlet 2212 of the centrifugal fan 22. The fin assembly 23 includes a plurality of spaced, parallel fins 231. A plurality of airflow channels 232 are defined in the fin assembly 23, with each airflow channel 232 being located between two corresponding neighboring fins 231. The airflow channels 232 are communicated with the fan air outlet 2212 of the centrifugal fan 22. The fin assembly 23 has a bottom surface 236 adjacent to the bottom cover 2213 of the centrifugal fan 22. In this embodiment, the bottom surface 236 is at the bottom of the plurality of fins 231 and substantially perpendicular to each of the fins 231. The bottom cover 2213 of the centrifugal fan 22 is substantially coplanar with the bottom surface 236 of the fin assembly 23. One side of the fin assembly 23 close to the fan air outlet 2212 of the centrifugal fan 22 defines a groove 233, for receiving the condensing section 212 of the heat pipe 21 therein. The fin assembly 23 is defined as having an air inlet portion 234 close to the fan air outlet 2212 of the centrifugal fan 22, and an air outlet portion 235 far away from the fan air outlet 2212 of the centrifugal fan 22.

The heat absorbing plate 24 is a rectangular plate, and is made of high thermal conductivity material, such as copper. One side of the heat absorbing plate 24 is attached to the electronic component 10 for absorbing the heat therefrom, and the other side of the heat absorbing plate 24 thermally connects to the evaporating section 211 of the heat pipe 21.

The casing 30 is located at one side of the heat dissipation device 20, close to the bottom cover 2213 and the bottom surface 236. The casing 30 defines a plurality of air vents 31. The air vents 31 are communicated with the airflow channels 232 of the fin assembly 23.

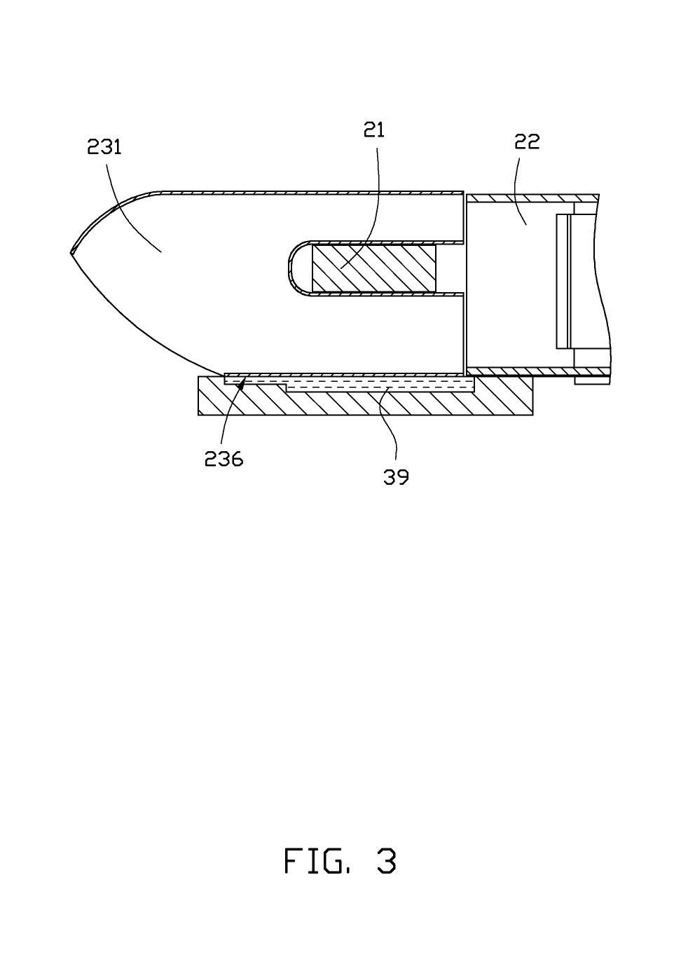

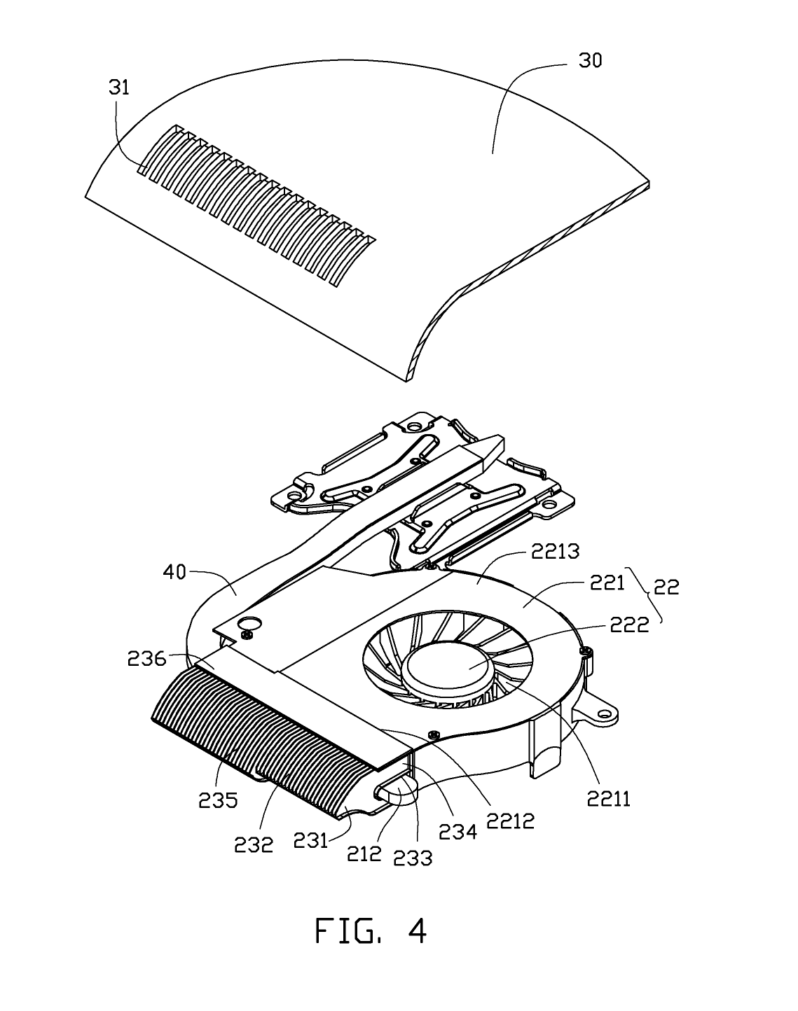

The heat insulation layer 40 is directly located on the bottom surface 236 of the fin assembly 23. In the illustrated embodiment, the heat insulation layer 40 protrudes from an inner side of the fin assembly 23 such that the heat insulation layer 40 also covers a small part of the bottom cover 2213 of the centrifugal fan 22. In this embodiment, the heat insulation layer 40 is an aerogel sheet. The aerogel is a low density, low thermal conductivity material, and so has a good heat insulation effect. The aerogel sheet can be directly attached the bottom surface 236 of the fin assembly 23. Referring to FIG. 3, to make the heat insulation layer 40, the bottom surface 236 of the fin assembly 23 can be put in contact with aerogel solution 39 held in a mold or tray (not labeled), and then the aerogel solution 39 can be dried and thus adhered on the bottom surface 236. Further or alternatively, the heat insulation layer 40 can be directly located on portions of surfaces of the heat pipe 21 close to the casing 30 (see FIG. 4), and/or on other portions of the fin assembly 23 close to the casing 30.

During operation of the electronic device 100, the heat generated by the electronic component 10 is absorbed by the heat absorbing plate 24, then transferred to the evaporating section 211 of the heat pipe 21, and finally transferred to the fin assembly 23 via the connecting section 213 and the condensing section 212 of the heat pipe 21. The centrifugal fan 22 draws air through the fan air inlet 2211 into the frame 221, and drives the air to flow towards the air inlet portion 234 of the fin assembly 23. Due to the heat insulation layer 40 being located on the bottom surface 236 of the fin assembly 23, the heat is directly transferred to the air outlet portion 235 of the fin assembly 23 via the airflow channels 232 along the airflow direction of the centrifugal fan 22, and then transferred to the external environment via the air vents 31 of the casing 30.

Because the heat insulation layer 40 is formed on one side of the heat dissipation device 20 close to the casing 30, and because the heat insulation layer 40 is made of aerogel material, heat generated by the electronic component 10 is blocked from reaching the casing 30. Thereby, an increase in the temperature of the casing 30 is avoided. In addition, the aerogel sheet has a good thermal insulation effect even when it is relatively thin. Thereby, the heat insulation layer 40 can occupy a small space inside the electronic device 100, and facilitate miniaturization of the electronic device 100.

It is believed that the embodiments and their advantages will be understood from the foregoing description, and it will be apparent that various changes may be made thereto without departing from the spirit and scope of the disclosure or sacrificing all of its material advantages, the examples hereinbefore described merely being illustrative embodiments of the disclosure.

What is claimed is:

1. An electronic device comprising:
an electronic component;
a heat dissipation device positioned on the electronic component for dissipating heat generated by the electronic component;
a casing, the electronic component and the heat dissipation device being located at an inner side of the casing; and
a heat insulation layer located on the heat dissipation device and being close to the casing, the heat insulation layer being made of aerogel material.

2. The electronic device of claim 1, wherein the heat dissipation device comprises a centrifugal fan, a fin assembly adjacent to the centrifugal fan, and a heat pipe thermally connecting the fin assembly with the electronic component.

3. The electronic device of claim 2, wherein the heat insulation layer is located directly on a surface of the heat pipe close to the casing.

4. The electronic device of claim 2, wherein the centrifugal fan defines an air inlet and an air outlet communicated with the air inlet, and the fin assembly is located at the air outlet of the centrifugal fan.

5. The electronic device of claim 4, wherein the fin assembly comprises a bottom surface and a plurality of parallel fins each substantially perpendicular to the bottom surface, a plurality of airflow channels are defined in the fin assembly, with each airflow channel located between two corresponding neighboring fins, the bottom surface is close to the casing, and the heat insulation layer is formed on the bottom surface.

6. The electronic device of claim 5, wherein the casing defines a plurality of air vents therein, and the air vents are communicated with the airflow channels of the fin assembly.

7. The electronic device of claim 5, wherein the heat insulation layer is located directly on the bottom surface of the fin assembly.

8. The electronic device of claim 2, wherein the heat dissipation device further comprises a heat absorbing plate, one side of the heat absorbing plate is attached to the electronic component for absorbing heat, and the other side of the heat absorbing plate thermally connects to the heat pipe.

9. An electronic device comprising:
an electronic component;
a heat dissipation device positioned on the electronic component for dissipating heat generated by the electronic component, wherein the heat dissipation device comprises:
a centrifugal fan;
a fin assembly adjacent to the centrifugal fan; and
a heat pipe thermally connecting the fin assembly with the electronic component;
a casing, the electronic component and the heat dissipation device being located at an inner side of the casing;
a first heat insulation layer located directly on a bottom surface of the fin assembly and being close to the casing; and
a second heat insulation layer located directly on a surface of the heat pipe close to the casing;
wherein the first and second heat insulation layers are made of aerogel material.

10. The electronic device of claim 9, wherein the centrifugal fan defines an air inlet and an air outlet communicated with the air inlet, and the fin assembly is located at the air outlet of the centrifugal fan.

11. The electronic device of claim 10, wherein the fin assembly comprises a plurality of parallel fins each substantially perpendicular to the bottom surface, a plurality of airflow channels are defined in the fin assembly, with each airflow channel located between two corresponding neighboring fins, the bottom surface is close to the casing.

12. The electronic device of claim 11, wherein the casing defines a plurality of air vents therein, and the air vents are communicated with the airflow channels of the fin assembly.

13. The electronic device of claim 9, wherein the heat dissipation device further comprises a heat absorbing plate, one side of the heat absorbing plate is attached to the electronic component for absorbing heat, and the other side of the heat absorbing plate thermally connects to the heat pipe.
